(19) United States
(12) Patent Application Publication
(10) Pub. No.: US 2025/0374583 A1
(43) Pub. Date: Dec. 4, 2025

(54) HYBRID HfO2-BASED FERROELECTRIC FIELD EFFECT TRANSISTOR AND METAL-FERROELECTRIC-SEMICONDUCTOR CAPACITOR FOR TRAINING AND/OR FINE-TUNING

(71) Applicant: International Business Machines Corporation, Armonk, NY (US)

(72) Inventors: Nanbo Gong, White Plains, NY (US); Takashi Ando, Eastchester, NY (US); Guy M. Cohen, Ossining, NY (US)

(21) Appl. No.: 18/679,159

(22) Filed: May 30, 2024

(51) Int. Cl. H01L 29/66; H01L 29/51; H01L 29/78

(52) U.S. Cl. CPC H10D 30/0415; H10D 1/716; H10D 30/701; H10D 64/689

(57) ABSTRACT

Aspects of the invention include a semiconductor structure including a ferroelectric field effect transistor (FeFET) and a ferroelectric capacitor (FeCAP) on a substrate. The FeFET including a first channel portion of the substrate, an oxide interfacial layer on the first channel portion of the substrate, a crystalline ferroelectric dielectric on the oxide interfacial layer; and an upper electrode on the crystalline ferroelectric dielectric. The FeCAP including a second channel portion of the substrate, the crystalline ferroelectric dielectric on and in contact with the second channel portion of the substrate, a lower electrode on the crystalline ferroelectric dielectric wherein the lower electrode comprises a scavenging material and an upper electrode on the lower electrode. The FeCAP and FeFET can be part of a cross-bar array in which the FeCAP functions as a gradient accumulation device and the FeFET functions as a weight storage device.

### BACKGROUND

The present invention relates generally to the electrical, electronic and computer arts and, more particularly, to techniques for forming ferroelectric field effect transistors (FeFETs), metal-ferroelectric-semiconductor capacitors (MFS FeCAPs or FeCAPs) and the like.

### BRIEF SUMMARY

Principles of the invention provide techniques for forming a FeFETs and FeCAPs on the same substrate to be used in cross-bar arrays of neural networks. Neural networks (NN) require much computational power and run into bottlenecks as the processor must often fetch data from memory. A solution is in-memory computing, an architectural design which allows parallel in-situ computing by organizing devices into cross-bar arrays. The arrays simultaneously store and process data locally and in parallel. Ferroelectric cross bars consist of ferroelectric capacitors (FeCAPs) and ferroelectric field effect transistors (FeFETs). Deep learning requires training a neural network (NN) using algorithms. A NN typically has may layers, and once the NN is trained, it can be used for inference. In some cases, it may be desirable to fine-tune the NN (i.e., not train from scratch, but fine-tune some of the layers in the pre-trained NN). In the training case, one exemplary algorithm is called Tiki-Taka, matrix A is used for frequent update, and matrix C is used to store weights for the NN. For the fine tune case, FeFETs can be used to store pre-trained NN weights, and FeCAPs can be used for weight update.

In one aspect, a semiconductor structure includes a substrate having a plurality of channel portions, a ferroelectric field effect transistor (FeFET) and ferroelectric capacitor (FeCAP) on the substrate. The FeFET includes a first channel portion of the substrate, an oxide interfacial layer on the first channel portion of the substrate, a crystalline ferroelectric dielectric on the oxide interfacial layer, and an upper electrode on the crystalline ferroelectric dielectric. The FeCAP including a second channel portion of the substrate, the crystalline ferroelectric dielectric on and in contact with the second channel portion of the substrate, a lower electrode on the crystalline ferroelectric dielectric wherein the lower electrode comprises a scavenging material, and the upper electrode on the lower electrode.

In another aspect, a cross bar array includes a weight storage device and a gradient accumulation device on a substrate. The weight storage device includes an FeFET having a first channel portion of the substrate, an oxide interfacial layer on the first channel portion of the substrate, a crystalline ferroelectric dielectric on the oxide interfacial layer, and an upper electrode on the crystalline ferroelectric dielectric. The gradient accumulation device including a FeCAP having a second channel portion of the substrate, the crystalline ferroelectric dielectric on and in contact with the second channel portion of the substrate, a lower electrode on the crystalline ferroelectric dielectric wherein the lower electrode comprises a scavenging material, and the upper electrode on the lower electrode.

In still a further aspect, an exemplary method of making a semiconductor structure includes providing a substrate having a first area and a second area, forming an oxide interfacial layer on the substrate, forming a ferroelectric dielectric on the oxide interfacial layer, forming a scavenger material in the second area of the substrate, annealing the substrate to form a crystallize ferroelectric dielectric in the first and the second areas and to migrate the oxygen from the oxide interfacial layer to form an oxidized scavenger material in the second area thereby leaving the oxide interfacial layer in the first area of the substrate while removing the oxide interfacial layer in the second area of the substrate, and forming an upper electrode in the first and second areas.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
Exploit the non-volatile and non-disturb read of an FeFET and combine with the endurance of an FeCAP structure on the same substrate to create a neural network with different, and therefore flexible, specifications such as retention, endurance and non-disturb read to use for a variety of tasks;
Use the hybrid FeFET/FeCAP monolithic substrate for fine tuning and training of deep learning applications (e.g. Tiki-Taka matrix A, C training).

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 depicts an exemplary gate first process flow for manufacturing a monolithic ferroelectric field effect transistor and ferroelectric capacitor in accordance with aspects of the invention;

FIGS. 2A through 2F depict cross-sections of steps in the exemplary gate first process flow of FIG. 1 in accordance with aspects of the invention;

FIG. 3 depicts an exemplary gate last process flows for manufacturing a monolithic ferroelectric field effect transistor and ferroelectric capacitor in accordance with aspects of the invention; and

FIGS. 4A through 4G depict cross-sections of steps in the exemplary gate last process flows of FIG. 3 in accordance with aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

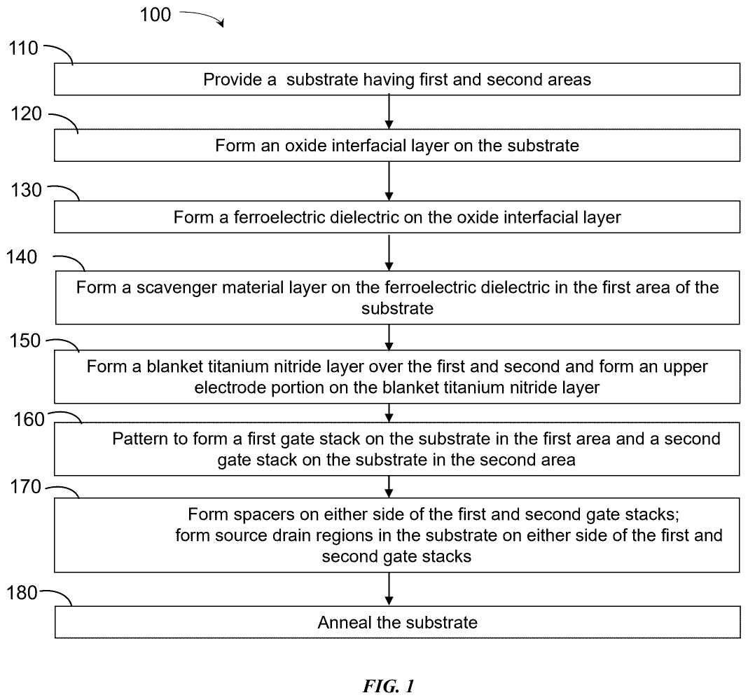

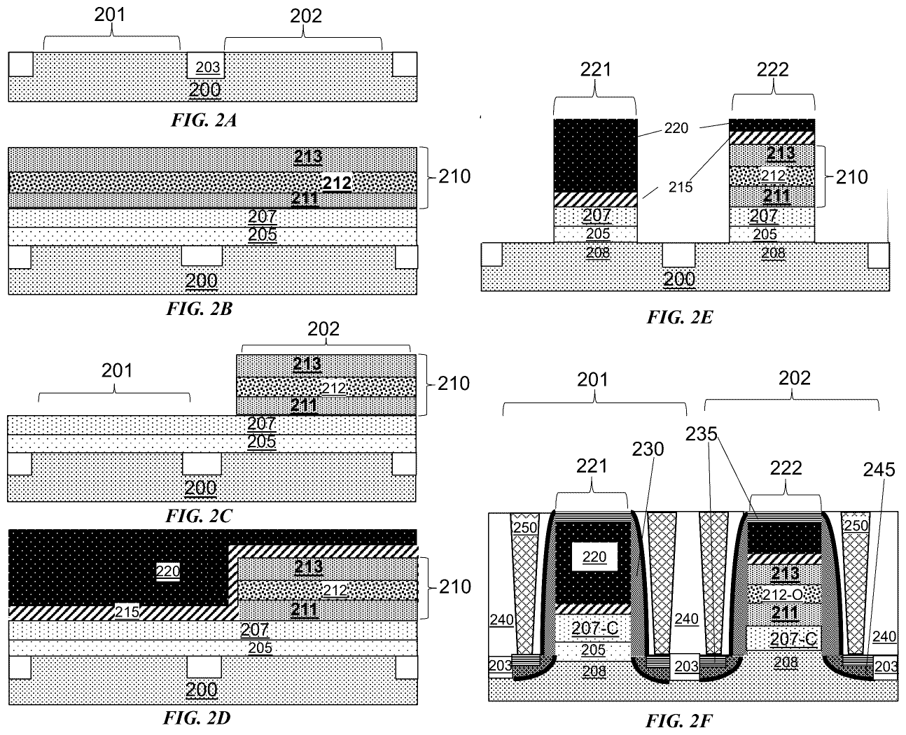

FIG. 1 lists aspects of an exemplary gate-first method 100 for forming a FeFET and a FeCAP on the same substrate while FIGS. 2A-2E are cross-sections of a substrate at selected points of FIG. 1. In step 110 of FIG. 1 a substrate is provided. Referring to FIG. 2A, the substrate 200 can be any semiconductor material or semiconductor on insulator substrate. Advantageously, the substrate 200 includes silicon. The substrate 200 can have 2 sections namely a first area 201 and the second area 202. The two areas can't be separated by one or more isolation areas 203.

In step 120 an oxide interfacial layer 205 is formed over the substrate 200. The oxide interfacial layer can be from 1 angstrom to about 20 angstroms and formed by oxidation of the substrate 200. In step 130 a ferroelectric dielectric 207 layer is formed on the oxide interfacial layer 205. In step 140 a scavenging layer 210 is formed over the ferroelectric dielectric 207 layer and the oxide interfacial layer 205. The scavenging layer 210 can be a tri-layer which includes a middle scavenger material 212 sandwiched by a first layer 211 and a second layer 212. The first and second layers can be the same or different conductive materials from each other. Advantageously, the first and second layers are suitable materials for a gate stack. The first and second layers physically isolate the scavenger material 212 while still allowing for a scavenging effect related to oxygen vacancy movement during a subsequent anneal step. In some embodiments, the first and second layers can be titanium nitride. FIG. 2B shows an exemplary substrate cross-section after forming the various layers of scavenger layer 210 according to an aspect of the invention. Alternatively, in another aspect of the invention, the scavenging layer 210 can be a titanium nitride doped with a scavenging material 212. Here, the titanium nitride and scavenger material 212 can be deposited, for example, by physical vapor deposition or reactive sputtering. The ferroelectric dielectric 207 can be any dielectric material that is both suitable as a gate dielectric and is ferroelectric. A non-limiting example of a ferroelectric dielectric 207 in accordance with aspects of the invention can be doped or undoped hafnium oxides. A doping element of the ferroelectric dielectric can include one or more of Al, Ca, Ce, Dy, Er, Gd, Ge, La, N, Sc, Si, Sr, Sn, Y, or Zr and mixtures thereof. As deposited, the ferroelectric dielectric 207 material will likely not be in a ferroelectric phase, but can become so in a subsequent anneal. The scavenger material 212 can be one or more of scavenging elements including Al, Ba, Be, Ca, Ce, Dy, Er, Hf, La, Lu Mg, Pr, Sc, Sr, Ti, Y, Zr or mixtures thereof. The scavenger material 212 can be TiN doped with a scavenging element.

Step 140 continues to pattern the layers formed on the substrate 200 so that the full stack of layers remains in the second area 202 of the substrate 200, while the first area 201 is left with the oxide interfacial layer 205 and the ferroelectric dielectric 207 layer (see FIG. 2C). Patterning can occur using conventional lithographic masking and etching.

In step 150, a blanket titanium nitride layer 215 is formed over the first area 201 and second area 202 of the substrate 200. An upper electrode 220 is formed over the blanket titanium nitride layer 215 in both areas. The upper electrode 220 is polished to form a planar surface (see FIG. 2D). The upper electrode 220 can be one or more of polysilicon, tungsten or any other suitable gate electrode material.

In step 160, the various layers are patterned using lithographic and etching techniques to form a first gate stack 201 on the substrate 200 in the first area 201 a second gate stack 202 on the substrate 200 in the second area 202 (see FIG. 2E). The area of the substrate 202 immediately under the gate stacks are the channel portions 208.

In step 170, spacers 230 and source/drain 245 regions are formed on either side of the first and second gate stacks. Silicides 235 can be formed on top and on either side of the first and second gate stacks. An insulating layer 240 is formed over the substrate and planarized. Contacts 250 are formed through the insulator 240 to make electrical contact to the source/drain 245 region(s) (see FIG. 2F). Between the source/drain 245 regions and under the gate stacks are the channel portions 208 of the substrate 200; a first channel portion 208 being in the first area 201 of the substrate 200 and a second channel portion 208 being in the second area 202 of the substrate

In step 180, the substrate 200 is annealed. Annealing can achieve several things, first it can activate the dopant of the source/drain 245 regions, second it can crystallize the ferroelectric dielectric 207 to form a crystalline ferroelectric dielectric 207-C (here, crystalline includes either single or polycrystalline materials) so that the material is now in a ferroelectric phase, and third it can activate scavenging of the oxide interfacial 205 layer by the scavenging material 212. In a gate first method 100, the annealing temperature can be greater than 600 C. During the scavenging process, oxygen from the oxide interfacial layer 205 migrates to the scavenging material 212 to form an oxide of the scavenging material (represented by 212-O) thereby eliminating the oxide interfacial layer 205. As a result, referring to FIG. 2F, the first area 201 of the substrate contains a FeFET while the second area 202 of the substrate contains a FeCAP. The gate stack of the FeFET (i.e. the first gate stack 221), is a top a channel region of the first area 201 of the substrate 200. The FeFET gate stack includes the oxide interfacial layer 205 on the channel, the crystallized ferroelectric dielectric 207-C on the oxide interfacial layer 205, the blanket titanium nitride layer 215, the crystallized ferroelectric dielectric 207-C and the upper electrode 220 on the blanket titanium nitride layer 215. The gate stack of the FeCAP (i.e. the second gate stack 220), is a top a channel region of the second area 202 of the substrate 200. The FeCAP gate stack includes the crystallized ferroelectric dielectric 207-C on the channel, the tri-layer on the crystallized ferroelectric dielectric 207-C where the post-anneal tri-layer includes a first layer and a second layer sandwiching oxide of the scavenging material, the blanket titanium nitride layer 215 on the tri-layer, and the upper electrode 220 on the blanket titanium nitride layer 215. The post-anneal tri-layer can be viewed as a lower electrode of the FeCAP.

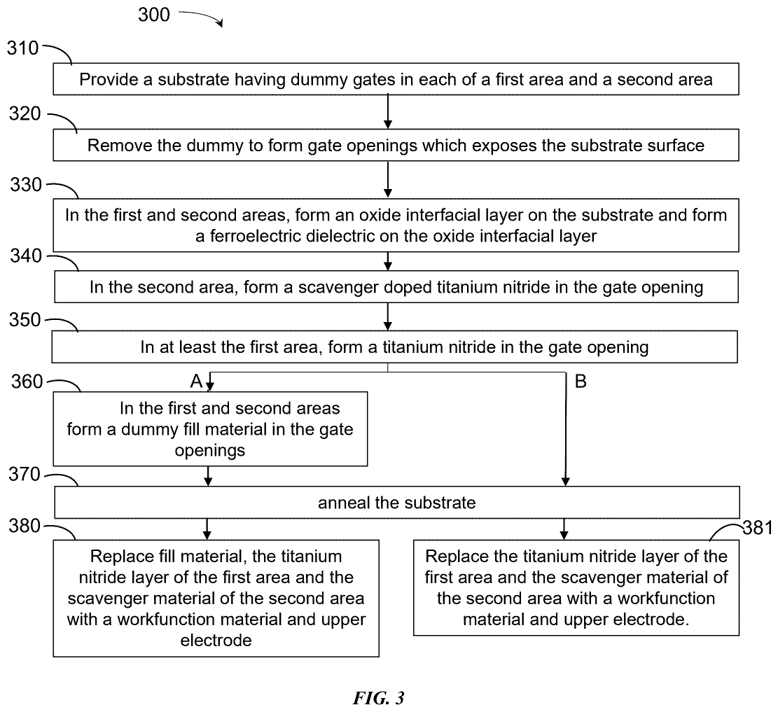

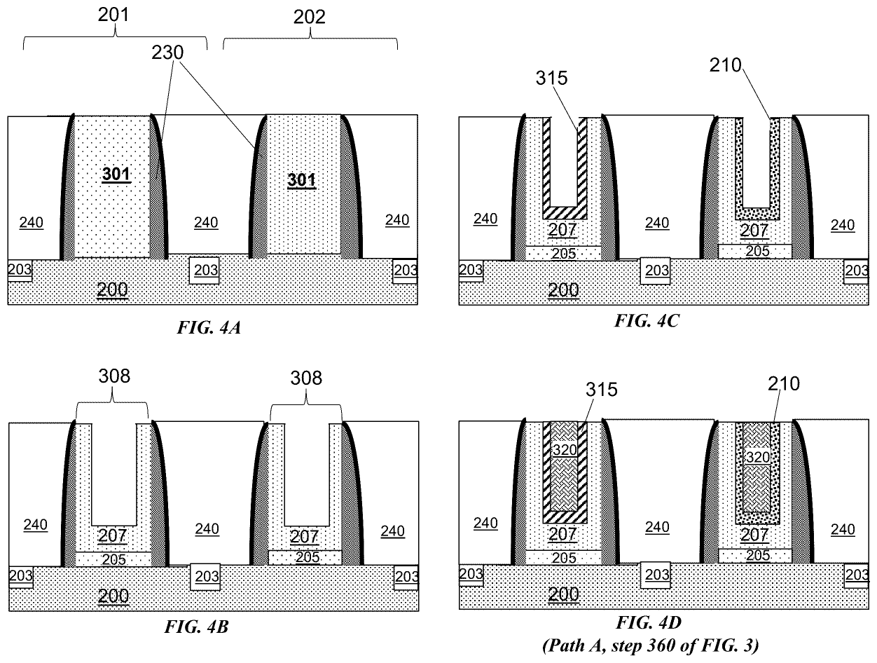

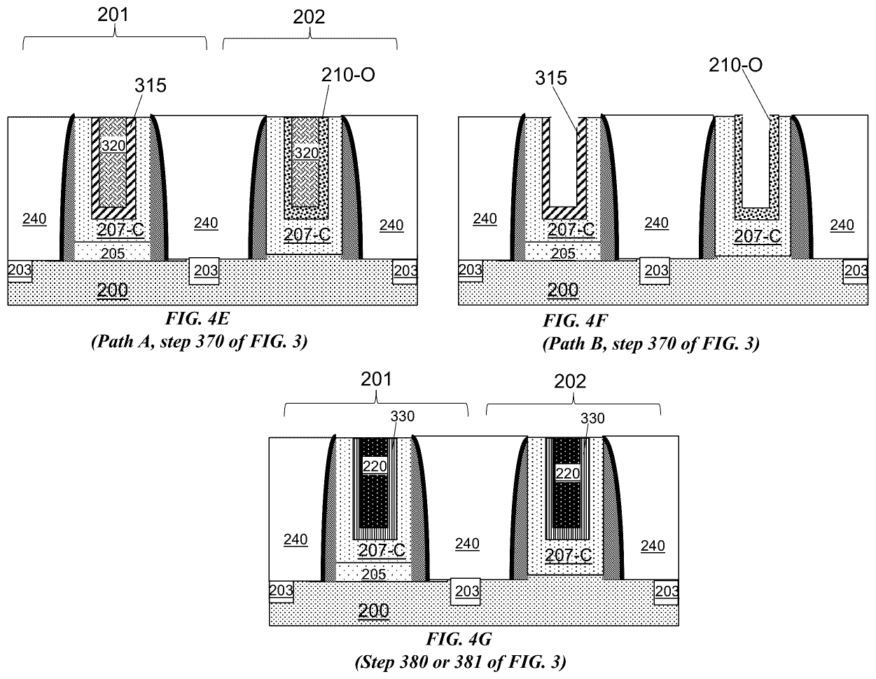

FIG. 3 lists aspects of an exemplary gate last methods 300 for forming a FeFET and a FeCAP on the same substrate while FIGS. 4A-4G are cross-sections of a substrate at selected points of FIG. 3. With regard to FIGS. 3 and 4A-4G, reference numerals repeated from FIGS. 1 and 2A-2F have the same meaning as previously described.

In step 310 of FIG. 3 and referring to the FIG. 4A cross-section, a substrate 200 is provided which has first area 201 and second area 202 separated by one or more isolation areas 203. In each area there is a dummy gate 301 on the substrate 200 flanked by spacers 230 and laterally surrounded by insulating layers 240. The dummy gate 301 can be polysilicon or amorphous silicon.

In step 320 of FIG. 3, the dummy gates 301 are removed in both areas to create gate openings 308 to expose the substrate 200 between the spacers 230. In step 330 and referring to the FIG. 4B cross-section, an oxide interfacial layer 205 is grown on the expose substrate 200 surface of each of the first area 201 and second area 202. A ferroelectric dielectric 207 is conformally deposited on the oxide interfacial layer 205 in each of the gate openings 308 and subsequently polished to be co-planar with insulating layers 240.

In step 340 of FIG. 3 and referring to the FIG. 4C cross-section, A scavenging layer 210 is conformally deposited on the ferroelectric dielectric 207 in each of the gate openings 308. Using lithographic and etching techniques, the scavenging layer 210 is removed from the first area 201 of the substrate 200. Next in step 350 of FIG. 3 and still referring to FIG. 4C cross-section, a titanium nitride 315 layer is conformally formed in at least the first area 201 of the substrate 200.

After step 350, there are two options for process flows, the “A” and “B” flows of FIG. 3. In the “A” flow, at step 360 and referring to FIG. 4D cross-section, a dummy fill 320 material is formed in the gate openings 308 and planarized. Referring to the “B” flow, it skips the dummy fill 320.

In step 370, an annealing takes place in both the “A” and “B” flows. Here, as in the previously described annealing step of FIG. 1, the crystallization of the ferroelectric dielectric takes place as indicated by 207-C as does the migration of oxygen from the oxide interfacial layer 205 to the scavenger material of the scavenger layer 210 to form an oxide as indicated by 210-O. In the “A” flow, the anneal can be greater than 600 C while in the “B” flow the anneal can be in the range of 300 C to 600 C. The difference in temperature of process flows has do with two items; first, at what temperature the ferroelectric dielectric (e.g. HfO₂) will crystallize into the ferroelectric phase, and second, whether or not any polysilicon is present. If there is polysilicon, the anneal will be greater than 600 C. Second, and if there is no polysilicon present at the time of the anneal, the anneal range of 300 C to 600 C can be used depending upon the doping of the ferroelectric dielectric. See FIGS. 4E and 4F for cross-sections post-anneal for flows “A” and “B”, respectively.

In step 380, in the gate openings 380, any materials above the crystalline ferroelectric 207-C of the first area 201 and second area 202 are removed and replaced with a workfunction material 330 and upper electrode 220 material. Workfunction materials 330 can include one or more of metal nitrides (e.g. TiN, WN), or Ti or Al and their alloys (e.g. TiAlC, TiAl, AlC). Therefore, regardless of gate last 300 method flow followed (e.g. “A” or “B”), the FIG. 4G cross-section results.

In all aspects discussed in this disclosure of monolithic FeFET/FeCAP structures, the FeCAP layer lacks an interfacial layer. The lack of interfacial layer results in fewer trap generation and longer endurance. As a result the monolithic FeFET/FeCAP can be used in neural networks, and advantageously used for training and fine tuning of neural networks. In particular, the FeFET operating as a three-terminal device (source, drain, gate) while the FeCAP operating as 2-terminal (source/drain, gate) can be used in fine tuning for information storage (which requires less frequent updating but longer retention and non-disturb read) and fine tuning (which requires more frequent updating and better endurance), respectively; while in training applications the FeFET can be used for Tiki-Taka C while the FeCAP is used for Tiki-Taka A. The FeFET can be used in cross-bar arrays that serve as weight storage for a neural network while the FeCAP can be used in cross-bar arrays that serve as gradient accumulation for a neural network.

In summary, in one aspect, a semiconductor structure includes a substrate 200 having a plurality of channel portions 208, a ferroelectric field effect transistor (FeFET) and ferroelectric capacitor (FeCAP) on the substrate. The FeFET includes a first channel portion 208 of the substrate 200, an oxide interfacial layer 205 on the first channel portion 208 of the substrate 200, a crystalline ferroelectric dielectric 207-C on the oxide interfacial layer 205, and an upper electrode 220 on the crystalline ferroelectric dielectric 207-C. The FeCAP including a second channel portion of the substrate 200, the crystalline ferroelectric dielectric 207-C on and in contact with the second channel portion 208 of the substrate, a lower electrode on the crystalline ferroelectric dielectric 207-C wherein the lower electrode comprises a scavenging material 212, and the upper electrode 220 on the lower electrode. Optionally, the crystalline ferroelectric dielectric 207-C comprises crystalline hafnium oxide. Optionally, the crystalline ferroelectric dielectric 207-C can be doped or undoped. When doped, the doping elements include one or more of Zr, Al, Ca, Ce, Dy, Er, Gd, Ge, La, N, Sc, Si, Sr, Sn or Y.

Optionally, the semiconductor structure's lower electrode comprises titanium, nitrogen and an oxide of a scavenger material. The scavenger material 212 can be one of Al, Be, Mg, Ca, Sr, Ba, Sc, Y, La, Ti, Zr, Hf, Dy, Lu, Er, Pr, Ce or mixtures thereof.

Optionally, the semiconductor structure's lower electrode includes a tri-layer (i.e. scavenger layer 210) including a first titanium nitride layer, an oxide of a scavenger material 212 on the first titanium nitride layer, and a second titanium nitride oxide of a scavenger material 212.

In another aspect a cross bar array includes a weight storage device and a gradient accumulation device on a substrate. The weight storage device includes an FeFET having a first channel portion 208 of the substrate 200, an oxide interfacial layer 205 on the first channel portion of the substrate 200, a crystalline ferroelectric dielectric 207-C on the oxide interfacial layer 205, and an upper electrode 220 on the crystalline ferroelectric dielectric 207-C. The gradient accumulation device including a FeCAP having a second channel portion of the substrate 200, the crystalline ferroelectric dielectric 207-C on and in contact with the second channel portion of the substrate, a lower electrode on the crystalline ferroelectric dielectric 207-C wherein the lower electrode comprises a scavenging material 212, and the upper electrode 220 on the lower electrode. Optionally, the crystalline ferroelectric dielectric 207-C comprises crystalline hafnium oxide. Optionally, the crystalline ferroelectric dielectric 207-C can be doped or undoped. When doped, the doping elements include one or more of Zr, Al, Ca, Ce, Dy, Er, Gd, Ge, La, N, Sc, Si, Sr, Sn or Y.

Optionally, the lower electrode comprises titanium, nitrogen and an oxide of a scavenger material. The scavenger material 212 can be one of Al, Be, Mg, Ca, Sr, Ba, Sc, Y, La, Ti, Zr, Hf, Dy, Lu, Er, Pr, Ce or mixtures thereof.

Optionally, the lower electrode includes a tri-layer (i.e. scavenger layer 210) including a first titanium nitride layer, an oxide of a scavenger material 212 on the first titanium nitride layer, and a second titanium nitride oxide of a scavenger material 212.

In still a further aspect, an exemplary method of making a semiconductor structure includes providing a substrate 200 having a first area 201 and a second area 202, forming an oxide interfacial layer 205 on the substrate 200, forming a ferroelectric dielectric 207 on the oxide interfacial layer 205, forming a scavenger material 212 in the second area 202 of the substrate 200, annealing the substrate to form a crystallize ferroelectric dielectric 207-C in the first and the second areas and to migrate the oxygen from the oxide interfacial layer 205 to form an oxidized scavenger material 212-O in the second area 202 thereby leaving the oxide interfacial layer 205 in the first area 201 of the substrate 200 while removing the oxide interfacial layer 205 in the second area 202 of the substrate 200, and forming an upper electrode 220 in the first area 201 and second area 202. Optionally, the annealing temperature is greater than 600 C.

Optionally, the method further forming a dummy gate 301 having spacers 230 in each of the first area 201 and second area 202 of the substrate 200, removing the dummy gate 301 in each of the first area 201 and second area 202 to form a gate opening 308 between the spacers 230 which exposes a substrate surface. And also includes forming an undoped titanium nitride layer in the gate opening 308 of the first area 201 of the substrate 200, and forming a workfunction material 330 and an upper electrode 220 in the gate opening 308 of the first area 201 and second area 202 of the substrate 200. The oxide interfacial layer 205 is formed on the substrate surface in the first area 201 and second area 202 of the substrate 200. The scavenger material 212 is a metal doped titanium nitride layer. After annealing, the oxide interfacial layer 205 on the substrate surface in the first area 201 of the substrate 200 remains while the oxide interfacial layer 205 on the substrate surface in the second area 202 of the substrate 200 is removed. Optionally, an annealing temperature is between 300 C-600 C.

In another option, the method further includes prior to annealing, forming a dummy fill 320 material in the gate opening 308 of the first area 201 and second area 202 of the substrate 200, and after annealing, removing the dummy fill 320 material, the titanium nitride layer and the oxidized scavenger material to expose the crystallized ferroelectric dielectric 207-C in the gate opening 308 of the first area 201 and second area 202 of the substrate 200. An annealing temperature can be greater than 600 C.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P.H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. §1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
a substrate having a plurality of channel portions;
a ferroelectric field effect transistor (FeFET) on the substrate, the FeFET comprising:
a first channel portion of the substrate;
an oxide interfacial layer on the first channel portion of the substrate;
a crystalline ferroelectric dielectric on the oxide interfacial layer; and
an upper electrode on the crystalline ferroelectric dielectric; and
a ferroelectric capacitor (FeCAP) on the substrate comprising:
a second channel portion of the substrate;
the crystalline ferroelectric dielectric on and in contact with the second channel portion of the substrate;
a lower electrode on the crystalline ferroelectric dielectric wherein the lower electrode comprises a scavenging material; and
the upper electrode on the lower electrode.

2. The semiconductor structure of claim 1, wherein the crystalline ferroelectric dielectric comprises crystalline hafnium oxide.

3. The semiconductor structure of claim 1, wherein the crystalline ferroelectric dielectric is undoped.

4. The semiconductor structure of claim 1, wherein the crystalline ferroelectric dielectric further comprises one or more doping elements.

5. The semiconductor structure of claim 4, wherein the doping elements comprise Zr, Al, Ca, Ce, Dy, Er, Gd, Ge, La, N, Sc, Si, Sr, Sn or Y.

6. The semiconductor structure of claim 1, wherein the lower electrode comprises titanium, nitrogen and an oxide of a scavenger material; and wherein the scavenger material is one of Al, Be, Mg, Ca, Sr, Ba, Sc, Y, La, Ti, Zr, Hf, Dy, Lu, Er, Pr, Ce or mixtures thereof.

7. The semiconductor structure of claim 6, wherein the lower electrode comprises:
a first titanium nitride layer;
an oxide of a scavenger material on the first titanium nitride layer;
and a second titanium nitride oxide of a scavenger material.

8. A cross-bar array comprising:
a substrate having a first channel portion and a second channel portion;
a weight storage device on the substrate; and
a gradient accumulation device the substrate;
wherein the weight storage device comprises:
a ferroelectric field effect transistor (FeFET) comprising:
an oxide interfacial layer on the first channel portion of the substrate;
a crystalline ferroelectric dielectric on the oxide interfacial layer; and
an upper electrode on the crystalline ferroelectric dielectric;
wherein the gradient accumulation device comprises:
a ferroelectric capacitor (FeCAP) comprising:
the crystalline ferroelectric dielectric on and in contact with the second channel portion of the substrate;
a lower electrode on the crystalline ferroelectric dielectric wherein the lower electrode comprises a scavenging material; and
the upper electrode on the lower electrode.

9. The semiconductor structure of claim 8, wherein the crystalline ferroelectric dielectric comprises crystalline hafnium oxide.

10. The semiconductor structure of claim 8, wherein the crystalline ferroelectric dielectric is undoped.

11. The semiconductor structure of claim 8, wherein the crystalline ferroelectric dielectric further comprises one or more doping elements.

12. The semiconductor structure of claim 11, wherein the doping elements comprise Zr, Al, Ca, Ce, Dy, Er, Gd, Ge, La, N, Sc, Si, Sr, Sn or Y.

13. The semiconductor structure of claim 11, wherein the lower electrode comprises titanium, nitrogen and an oxide of a scavenger material; and wherein the scavenger material is one of Al, Be, Mg, Ca, Sr, Ba, Sc, Y, La, Ti, Zr, Hf, Dy, Lu, Er, Pr, Ce or mixtures thereof.

14. The semiconductor structure of claim 13, wherein the lower electrode comprises:
a first titanium nitride layer;
an oxide of a scavenger material on the first titanium nitride layer;
and a second titanium nitride oxide of a scavenger material.

15. A method of making a semiconductor structure comprising:
providing a substrate having a first area and a second area;
forming an oxide interfacial layer on the substrate;
forming a ferroelectric dielectric on the oxide interfacial layer;
forming a scavenger material in the second area of the substrate;
annealing the substrate to form a crystallize ferroelectric dielectric in the first and the second areas and to migrate the oxygen from the oxide interfacial layer to form an oxidized scavenger material in the second area thereby leaving the oxide interfacial layer in the first area of the substrate while removing the oxide interfacial layer in the second area of the substrate; and
forming an upper electrode in the first and second areas.

16. The method of claim 15, further comprising:
wherein forming the scavenger material comprises forming a tri-layer of titanium nitride/the scavenger material/titanium nitride on the ferroelectric dielectric in the second area of the substrate;
forming a blanket titanium nitride layer over the first and second areas of the substrate;
wherein the upper electrode is formed on the blanket titanium nitride layer;
patterning to form a first gate stack on the substrate in the first area and a second gate stack on the substrate in the second area;
wherein the first gate stack comprises the oxide interfacial layer, ferroelectric dielectric, the blanket titanium nitride layer and the upper electrode; and
wherein the second gate stack comprises the oxide interfacial layer, the ferroelectric dielectric, the tri-layer, the blanket titanium nitride layer and the upper electrode;
forming spacers on either side of the first and second gate stacks;
forming source drain regions in the substrate on either side of the first and second gate stacks;
wherein after annealing, the second gate stack comprises the crystallized ferroelectric dielectric, the final tri-layer of titanium nitride/the oxidized scavenger material/titanium nitride, the blanket titanium nitride layer and the upper electrode.

17. The method of claim 16, wherein an annealing temperature is greater than 600 C.

18. The method of claim 15, further comprising:
forming a dummy gate having spacers in each of the first and second areas of the substrate;
removing the dummy gate in each of the first and the second areas to form a gate opening between the spacers which exposes a substrate surface;
wherein the oxide interfacial layer is formed on the substrate surface in the first and second areas of the substrate;
wherein the scavenger material is a metal doped titanium nitride layer;
forming an undoped titanium nitride layer in the gate opening of the first area of the substrate;
wherein after annealing, the oxide interfacial layer on the substrate surface in the first area of the substrate remains while the oxide interfacial layer on the substrate surface in the second area of the substrate is removed; and
forming a workfunction material and an upper electrode in the gate opening of the first and the second areas of the substrate.

19. The method of claim 18, where an annealing temperature is between 300 C-600 C.

20. The method of claim 18, further comprising:
prior to annealing, forming a dummy fill material in the gate opening of the first and the second areas of the substrate; and
after annealing, removing the dummy fill material, the titanium nitride layer and the oxidized scavenger material to expose the crystallized ferroelectric dielectric in the gate opening of the first and the second areas of the substrate;
wherein an annealing temperature is greater than 600 C.
